(19) United States
(12) Patent Application Publication
(10) Pub. No.: US 2010/0073870 A1
(43) Pub. Date: Mar. 25, 2010

(54) Electromagnetic field and wave shielding pad for laptops and netbook computers

(76) Inventor: Clemente Miguel Diez Munoz, Long Beach, CA (US)

Correspondence Address: Clemente Miguel Diez Munoz, 230 The Toledo, Long Beach, CA, 90803, US

(21) Appl. No.: 12/561,265

(22) Filed: Sep. 17, 2009

Related U.S. Application Data
(60) Provisional application No. 61/097,669, filed on Sep. 17, 2008.

(51) Int. Cl. H05K 9/00; H05K 7/00

(52) U.S. Cl. 361/679.55; 361/818

(57) ABSTRACT

An electromagnetic field and wave shielding pad for laptop and netbook computers against electromagnetic field and wave, generated by those devices and transferred to the user through contact with the wrists and palms of the hands. The electromagnetic field and wave shielding pad is made up of a lower layer pad, an electromagnetic shielding layer and an upper layer pad.

Both lower and upper layers are made of a rubber material; non-magnetic, self-adhesive on one of the sides, temperature-resistant, washable, removable, reusable, anti-violet light resistant. The electromagnetic shielding layer is made of a shielding material with a high concentration of nickel alloy or any other electromagnetic shielding material. The self adhesive side of the lower layer is adhered to the surface of the laptop, the non self adhesive side of the lower layer is adhered to the electromagnetic shielding layer by glue, the other side of the electromagnetic shielding layer is adhered to the self adhesive side of the upper layer, and the cushioned side of the upper layer is in contact with the palms and wrists of the user to provide a comfortable surface. A final thermo sealed treatment guarantees the unity of the three elements (layers).

This application claims priority to the provisional patent application No. 61/097,669 filed on Sep. 17, 2008.

### BACKGROUND OF THE INVENTION

1. Field of the Invention

The present invention relates to laptop and netbook computers, and more particularly pertains to a new removable electromagnetic field and wave shielding pad for shielding the user's palms of the hands and wrists from electromagnetic wave produced from laptops and netbook computers. Such removable shielding apparatus being reusable.

2. Description of the Prior Art

The use of electromagnetic shielding systems is known in the prior art. More specifically, electromagnetic shielding systems heretofore devised and utilized are known to consist basically of familiar, expected and obvious structural configurations, notwithstanding the myriad of designs encompassed by the crowded prior art which have been developed for the fulfillment of countless objectives and requirements.

Known prior art includes U.S. Pat. No. 7,171,248; U.S. Pat. No. 6,711,387; U.S. Pat. No. 6,359,216; U.S. Pat. No. 6,219,419. While these devices fulfill their respective, particular objectives and requirements, the aforementioned patents do not disclose a new electromagnetic field and wave shielding pad for laptop and network computers.

In these respects, the electromagnetic field and wave shielding pad for laptop and network computers according to the present invention substantially departs from the conventional concepts and designs of the prior art, and in so doing provides an apparatus primarily developed for the purpose of reducing the effects of electromagnetic field and wave by the laptop and network computers in the palms of the hands and wrists of the users.

### BRIEF SUMMARY OF THE INVENTION

In view of the foregoing disadvantages inherent in the known types of electromagnetic shielding systems now present in the prior art, the present invention provides a new electromagnetic shielding system construction wherein the same can be utilized for shielding the user's palms of the hands and wrists from electromagnetic wave produced from a laptop and netbook computer.

The general purpose of the present invention, which will be described subsequently in greater detail, is to provide a new electromagnetic shielding system apparatus and method which has many of the advantages of the electromagnetic shielding systems mentioned heretofore and many novel features that result in a new electromagnetic shielding system which is not anticipated, rendered obvious, suggested, or even implied by any of the prior art electromagnetic shielding systems, either alone or in any combinations thereof.

To attain this, the present invention generally comprises a lower pad formed of a rubber material; the electromagnetic shielding layer made of a electro magnetic shielding material with a high compound of nickel alloy (80%) or any other magnetic shielding element permanently affixed to the non-self adhesive side of the lower pad (the main function is to shield and reduce the electromagnetic field produced by the surface of the laptop/netbook computer at the location of the pad) and, the upper pad formed of a self adhesive material with the same characteristics of the lower pad whose non self adhesive side is cushioned surface for the comfort of the wrists and palms of the users.

There has thus been outlined, rather broadly, the more important features of the invention in order that the detailed description thereof that follows may be better understood, and in order that the present contribution to the art may be better appreciated. There are additional features of the invention that will be described hereinafter and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings.

The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and specially the scientists, engineers, and practitioners in the art who are not familiar with patent or legal terms or phraseology, to determine quickly from a cursory inspection the nature and essence of the technical disclosure of the application.

The abstract is neither intended to define the invention of the application, which is measured by the claims, nor is it intended to be limiting as to the scope of the invention in any way.

It is therefore an object of the present invention to provide a new electromagnetic shielding system apparatus and method which has many of the advantages of the electromagnetic shielding systems mentioned heretofore and many novel features that result in a new electromagnetic shielding systems which is not anticipated, rendered obvious, suggested, or even implied by any of the prior art electromagnetic shielding systems, either alone or in any combination thereof.

It is another object of the present invention to provide a self adhesive electromagnetic shielding pad for use on laptops and netbook computers against electromagnetic field and wave, generated by those devices and transferred to the user through contact with the wrists and palms.

It is another further object of the present invention to provide a new electromagnetic shielding system which also protects the laptop and netbook computers' surface from the effects of bodily (hands) sweat and provides a pleasant and cushioned surface for the laptop user's wrists and palms.

An even further object of the present invention is to provide a new electromagnetic shielding system which may be easily and efficiently manufactured and, marketed.

Still yet another object of the present invention is to provide a new electromagnetic shielding system which is of a durable and reliable construction.

Still yet another object of the present invention is to provide a new electromagnetic shielding system which is susceptible of a low cost of manufacture with regard to both materials and labor, and which accordingly is then susceptible to low prices of sale to the consuming public, thereby making such electromagnetic shielding system economically available to the buying public.

Still yet another object of the present invention is to provide a new electromagnetic shielding system which provides in the apparatuses and methods of the prior art some of the advantages thereof, while simultaneously overcoming some of the disadvantages normally associated therewith.

Even still yet another object of the present invention is to provide a new electromagnetic shielding pad for laptops and netbook computers that reduces immediate exposure of the palms of the hands and wrists to the electromagnetic wave and field created by those devices.

Even still another object of the present invention is to provide a new electromagnetic shielding pad for laptops and netbook computers that serves as protection to one's health.

These together with other objects of the invention, along with the various features of novelty which characterize the invention, are pointed out with particularity in the claims annexed to and forming a part of this disclosure. For a better understanding of the invention, its operating advantages and the specific objects attained by its uses, reference should be made to the accompanying drawings and descriptive matter in which there are illustrated preferred embodiments of the invention.

### BRIEF DESCRIPTION OF THE DRAWINGS

The invention will be better understood and objects other than those set forth above will become apparent when consideration is given to the following description thereof. Such description makes reference to the annexed drawings wherein:

FIG. 1 is a front perspective view of a new electromagnetic field and wave shielding pad for laptops and netbook computers according to the present invention;

FIG. 2 is a cross-sectional view of FIG. 1;

FIG. 3 is an environmental view showing the pad being mounted to a laptop/netbook computer.

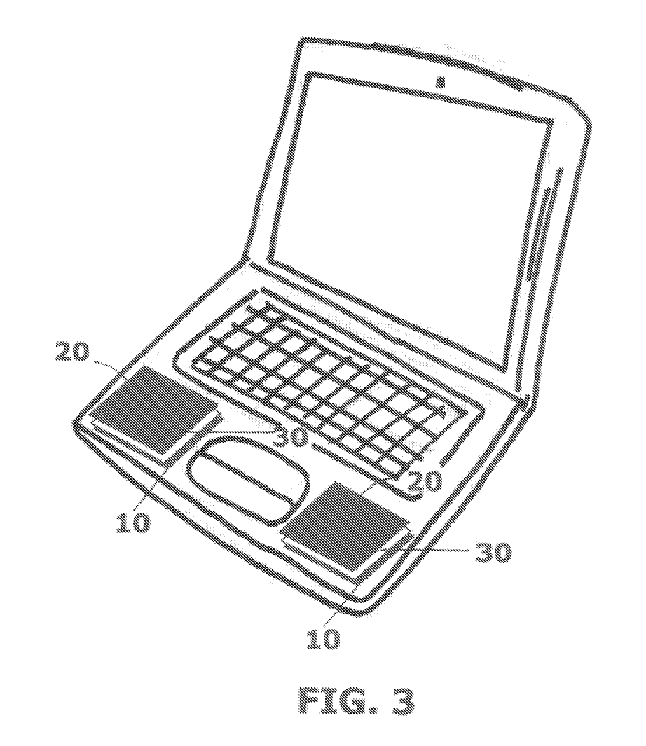

### DETAILED DESCRIPTION OF THE PREFERRED EMBODIMENTS

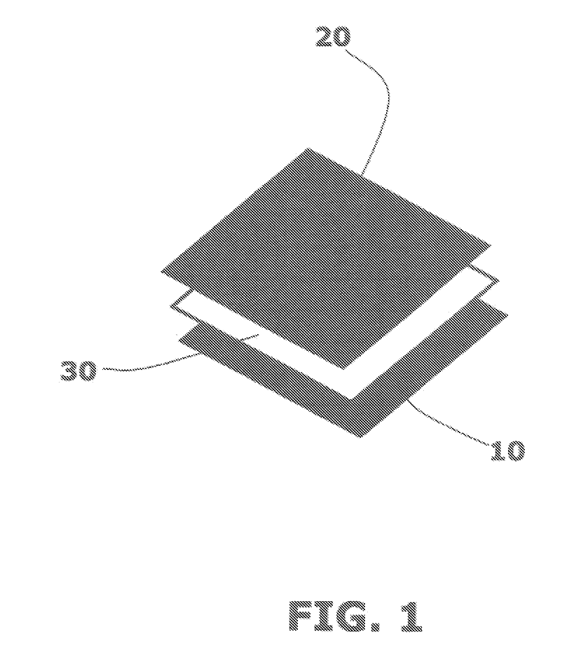

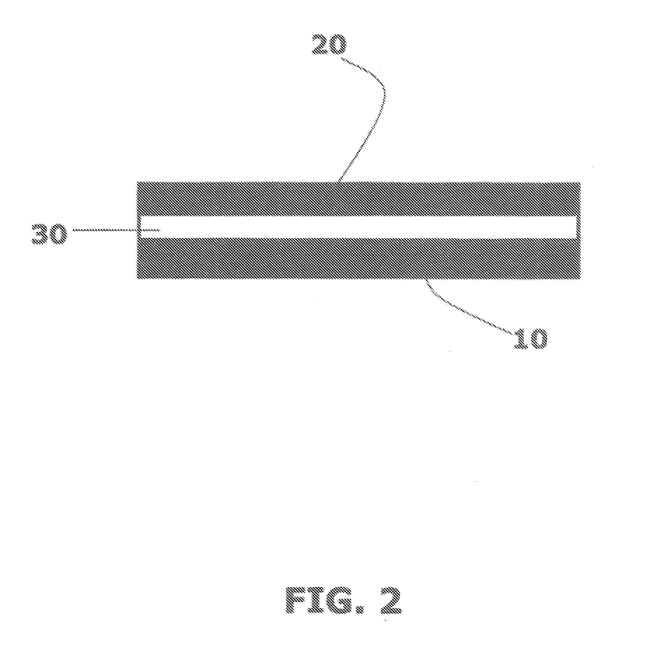

Referring to FIGS. 1 and 2, there is shown an electromagnetic field and wave shielding pad for laptops and netbook computers constructed in accordance with the invention. The device comprises a lower pad 10, an upper pad 20, and an electromagnetic shielding pad 30. Each of the above components is detailed below.

Lower pad 10 is formed of a rubber material; non-magnetic, self-adhesive (on one side), temperature-resistant, washable, removable, reusable, anti-violet light resistant that adheres to the laptop/netbook computer surface by its self adhesive side.

Upper pad 20 is the same size as lower pad 10. Upper pad 20 is formed of the same material as lower pad 10 being one of the sides self adhesive while the other side is a cushioned surface for the comfort of the wrists and palms of the users.

The electromagnetic shielding pad 30; has the feature of shielding electromagnetic field and wave. The shielding pad 30 is the same size as the pads 10 and 20 and, is formed of a high compound of nickel alloy or any other electromagnetic shielding material permanently glued to: the non-self adhesive side of the lower pad 10 and the self adhesive side of the upper pad 20.

The electromagnetic field and wave shielding pad for laptops and netbook computers FIGS. 1 and 2 can be made in squared, rectangular, elliptic shape or any other geometric shapes desired to conform to various shapes of laptop and network computers so as to cover as much of the surface where the palms of the hands and wrists rest while typing.

Referring to FIG. 6, the mounting of the shield device of the invention to the laptop/netbook computer is illustrated. It is seen that the bottom self adhesive surface 24 of the lower pad 10 is adhered to the surface of the laptop/netbook computer 50. As such, there are no or little electromagnetic wave outside the adhered shield device due to the absorption of the shielding pad 30.

In summary, the advantages of the present invention are given as below:
1. The electromagnetic shielding laptop pads can be made in a squared, rectangular, elliptic or any other shapes so as to cover as much of the surface where the palms of the hands and wrists rest while typing.
2. The materials used to produce the shielding screen have no influence on the performance of the laptop/netbook computer.
3. It can be applied to various kinds of laptop/netbook computers with a decorative effect.
4. It can be applied to various kinds of laptop/netbook computers with a protective effect for the surface of the laptop/netbook from the effects of bodily (hands) providing d pleasant and cushioned surface for the laptop user's wrists and palms.
5. It has a permanent shielding effect against electromagnetic field and wave which will nor disappear as a result of use or cleaning.

As to further discussion of the manner of usage and operation of the present invention, the same should be apparent from the above description. Accordingly, no further discussion relating to the manner of usage and operation will be provided.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. An electromagnetic field and wave shielding pad for laptops and network computers to reduce the electro magnetic field and wave effects in the palms of the hands and wrists of the laptop/netbook user comprising:
A lower pad formed of a rubber material; non-magnetic, self-adhesive, temperature-resistant, washable, removable, reusable, anti-violet light resistant that adheres to the laptop surface—one side is self adhesive and can be re-stuck numerous times on the surface of the laptop/netbook computer.
An electromagnetic shielding layer formed of an electro magnetic shielding material with a high component of nickel alloy or any other electromagnetic shielding material. The electromagnetic shielding layer permanently glued to the non-self adhesive side of the lower pad and to the self adhesive side of the upper pad. Whereby electromagnetic field and wave coming from the laptop are substantially absorbed or shielded via the electro magnetic shielding laptop/netbook pad.
An upper pad formed with the same characteristics as the lower pad and with one of the sides (the non-adhesive) cushioned for the comfort of wrists and palms of the users. This upper pad is permanently glued to the electromagnetic shielding pad by its self adhesive side, being the cushioned side in touch with palms and wrists of the user.

2. The Electro Magnetic Field (EMF) shielding laptop pad of claim 1, wherein the lower, shielding and upper pads are squared.

3. The Electro Magnetic Field (EMF) shielding laptop pad of claim 1, wherein the lower, shielding and upper pads are circular.

4. The Electro Magnetic Field (EMF) shielding laptop pad of claim 1, wherein the shielding layer material is other than a high nickel concentrate.

5. The Electro Magnetic Field (EMF) shielding laptop pad of claim 1, wherein the lower pad, shielding layer and upper pad are connected with an adhesive.

6. The Electro Magnetic Field (EMF) shielding laptop pad of claim 5, wherein the adhesive is glue.
